(19) United States
(12) Patent Application Publication
(10) Pub. No.: US 2013/0023080 A1
(43) Pub. Date: Jan. 24, 2013

(54) CHEMICAL VAPOR DEPOSITION AND METHOD OF MANUFACTURING LIGHT-EMITTING DEVICE USING CHEMICAL VAPOR DEPOSITION

(71) Applicants: Bum-joon KIM, Seoul (KR); Ki-sung Kim, Gyeonggi-do (KR); Young-sun Kim, Gyeonggi-do (KR); Doek-gil Ko, Seoul (KR); Jin-young Lim, Gyeonggi-do (KR); Eui-joon Jeong, Seoul (KR)

(72) Inventors: Bum-joon KIM, Seoul (KR); Ki-sung Kim, Gyeonggi-do (KR); Young-sun Kim, Gyeonggi-do (KR); Doek-gil Ko, Seoul (KR); Jin-young Lim, Gyeonggi-do (KR); Eui-joon Jeong, Seoul (KR)

(21) Appl. No.: 13/358,189

(22) Filed: Jan. 25, 2012

(30) Foreign Application Priority Data
Jul. 20, 2011 (KR) 10-2011-0072074

(51) Int. Cl. H01L 21/205; H01L 33/06

(52) U.S. Cl. 438/47; 438/478; 257/E21.101; 257/E33.008

(57) ABSTRACT

A chemical vapor deposition (CVD) method includes forming a first semiconductor layer on a substrate that is mounted on a satellite disk at a first process temperature; and forming a second semiconductor layer on the first semiconductor layer at a second process temperature. Also, a method of manufacturing a light-emitting device (LED) includes: forming a quantum well layer on a substrate that is mounted on a satellite disk at a first process temperature; and forming a quantum barrier layer on the quantum well layer at a second process temperature.

### CROSS-REFERENCE TO RELATED APPLICATIONS

This application claims the benefit of Korean Patent Application No. 10-2011-0072074, filed on Jul. 20, 2011, in the Korean Intellectual Property Office, the disclosure of which is incorporated herein in its entirety by reference.

### BACKGROUND

1. Field

The present disclosure relates to a chemical vapor deposition (CVD) method and methods of manufacturing a light-emitting device using the CVD method, and more particularly, to a CVD method, in which different flowing gases are injected alternately to vary a process temperature, and methods of manufacturing an active layer of a light-emitting device (LED) using the CVD method.

2. Description of the Related Art

In general, a chemical vapor deposition (CVD) apparatus is an apparatus for forming a thin film on a deposition target, which usually includes substrates like a semiconductor wafer, using a chemical reaction. In detail, the CVD apparatus injects a reaction gas having a high vapor pressure to a substrate heated in a vacuum chamber so that a thin film of the reaction gas is grown on the substrate.

Recently, a CVD method such as a metal organic chemical vapor deposition (MOCVD) method is widely used, as semiconductor devices have become minute and light-emitting devices (LED) with a high efficiency and a high output are developed. Also, growing a thin film uniformly on a plurality of deposition targets to engender a deposition reaction on the plurality of deposition targets at once has become a core technology as sizes of chambers and susceptors increase. Here, the deposition targets are each placed on a satellite disk, and satellite disks are each accommodated in a plurality of pockets formed in the susceptor. To facilitate a uniform growth of thin films on the deposition targets, the susceptor itself is designed to rotate, and moreover, the satellite disks on which the deposition targets are placed are designed to rotate.

### SUMMARY

Additional aspects will be set forth in part in the description which follows and, in part, will be apparent from the description, or may be learned by practice of the presented embodiments.

According to an aspect of the present invention, a chemical vapor deposition (CVD) method includes: forming a first semiconductor layer on a substrate that is mounted on a satellite disk at a first process temperature; and forming a second semiconductor layer on the first semiconductor layer at a second process temperature, wherein the forming the first and second semiconductor layers is performed at least once.

The first and second process temperatures may be controlled by using the first and second flowing gases, respectively.

A thermal conductivity of the first flowing gas may be different from a thermal conductivity of the second flowing gas.

Each of the first and second flowing gases may include at least one selected from the group consisting of Ar, H₂, N₂, He, O₂, CO₂, and NH₃.

A difference between the first and second process temperatures may be from about 50° to about 150°.

The CVD method may further include forming a third semiconductor layer on the second semiconductor layer at a third process temperature.

According to another aspect of the present invention, a method of manufacturing a light-emitting device (LED) by using a chemical vapor deposition (CVD) method, includes: forming a quantum well layer on a substrate that is mounted on a satellite disk at a first process temperature; and forming a quantum barrier layer on the quantum well layer at a second process temperature, wherein the forming the quantum well layer and the quantum barrier layer is performed at least once.

The first and second process temperatures may be controlled by using the first and second flowing gases, respectively.

A thermal conductivity of the first flowing gas may be different from a thermal conductivity of the second flowing gas.

A thermal conductivity of the first flowing gas may be less than a thermal conductivity of the second flowing gas.

Each of the first and second flowing gases may include at least one selected from the group consisting of Ar, H₂, N₂, He, O₂, CO₂, and NH₃.

The first process temperature may be from about 900° to about 1200°.

The second process temperature may be from about 900° to about 1200°.

A difference between the first and second process temperatures may be from about 50° to about 150°.

The first flowing gas may include Ar, and the second flowing gas may include H₂.

The first flowing gas may include N₂, and the second flowing gas may include H₂.

Each of the quantum well layer and the quantum barrier layer may include at least one selected from the group consisting of GaN, GaInN, AlGaN, and AlGaInN.

The quantum well layer may include InₓGa₁₋ₓN (0≦x≦1).

The quantum barrier layer may include InₓGa₁₋ₓN (0≦x≦0.4).

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view illustrating a chemical vapor deposition (CVD) apparatus used in a chemical vapor deposition (CVD) according to an embodiment of the present invention;

FIG. 2 is a schematic cross-sectional view illustrating a light-emitting device (LED) manufactured by a method of manufacturing an LED according to an embodiment of the present invention;

FIG. 3 illustrates a variation in a process temperature and a substrate temperature according to a method of manufacturing an LED of the related art; and

FIG. 4 illustrates a variation in a process temperature and a substrate temperature according to a method of manufacturing an LED according to an embodiment of the present invention.

### DETAILED DESCRIPTION

Various example embodiments will now be described more fully with reference to the accompanying drawings in which some example embodiments are shown.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms ‘first’, ‘second’, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing example embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In the drawings, the thicknesses of layers and regions are exaggerated for clarity.

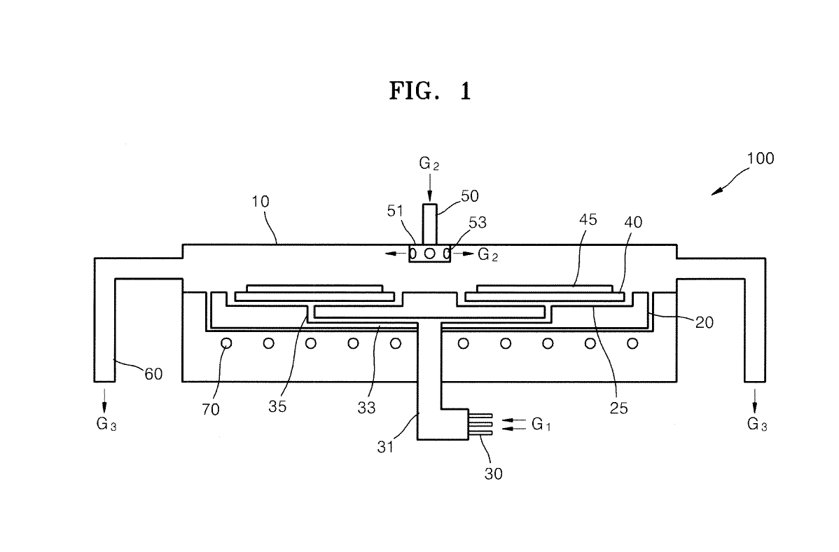

FIG. 1 is a schematic cross-sectional view illustrating a chemical vapor deposition (CVD) apparatus 100 used in a CVD method and a method of manufacturing a light-emitting device (LED) using the CVD method, according to an embodiment of the present invention. In particular, the CVD apparatus 100 may be a metal organic CVD (MOCVD) apparatus.

Referring to FIG. 1, the CVD apparatus 100 may include a susceptor 20 in which a plurality of pockets 25 are formed; a satellite disk 40 mounted on each of the pockets 25; a flowing gas injecting unit 31 supplying a flowing gas G₁ between the susceptor 20 and the satellite disk 40; a reaction gas injecting unit 50 supplying a reaction gas G₂, a chamber 10 accommodating the susceptor 20 and a nozzle 51 of the reaction gas injecting unit 50; and a gas discharging unit 60 discharging the flowing gas G₁ and the reaction gas G₂ in the chamber 10. Here, the flowing gas G₁ refers to susceptor gas.

The susceptor 20 may have a shape of disk, and the plurality of pockets 25 may be formed in an upper surface of the susceptor 20. The susceptor 20 may be formed of graphite or tungsten or the like, and may be hard-coated to reinforce durability. For example, the susceptor 20 may be formed by coating graphite with silicon carbide (SiC).

The pockets 25 may be a recess in a concave form formed at a predetermined depth from the upper surface of the susceptor 20. The disk-shaped satellite disk 40 may be accommodated in each of the pockets 25. A protrusion (not shown) in order to prevent the satellite disk 40 from separating during rotation, may be formed in a center portion of each of the pockets 25.

A susceptor flow path 33 through which the flowing gas G₁ is supplied to the plurality of pockets 25 may be formed inside the susceptor 20. The flowing gas G₁ may be discharged from a flowing gas discharging unit 35 through the susceptor flow path 33. Due to the discharged flowing gas G₁, the satellite disk 40 may float and rotate along a floating guide groove (not shown) formed in the pockets 25.

The flowing gas injecting unit 31 may be connected to a flowing gas supply line 30 to inject the flowing gas G₁ to the susceptor flow path 33. Rotation of the satellite disk 40 may be controlled by controlling a flow amount of the flowing gas G₁ supplied through the flowing gas supply line 30. The susceptor 20 may be heated to a predetermined temperature by a heater 70. For example, when growing a GaN-based semiconductor layer, the heater 70 may heat the susceptor 20 to a predetermined temperature of about 700° to about 1300°.

The reaction gas injecting unit 50 is a unit for supplying the reaction gas G₂, containing a source gas and a carrier gas, which is to be deposited on a substrate 45, which is a deposition target. The nozzle 51 of the reaction gas injecting unit 50 may be exposed in the chamber 10, thereby supplying the reaction gas G₂ to the chamber 10 via a nozzle hole 53 of the nozzle 51.

The substrate 45 such as a wafer may be disposed on the satellite disk 40. A rim (not shown) may be formed on an outer portion of the satellite disk 40 to fix the substrate 45. As the susceptor 20 is heated to a high temperature, the substrate 45 may maintain a high temperature and an upper surface of the substrate 45 may contact the reaction gas G₂ to cause a chemical deposition reaction. According to the chemical deposition reaction, a predetermined material such as a GaN-based compound semiconductor may be crystal-grown on the substrate 45 such as a wafer.

The chamber 10 may accommodate the susceptor 20 and the nozzle 51 of the reaction gas injecting unit 50; the chamber 10 may be sealed during a deposition operation and may be opened to exchange the substrate 45. Also, the gas discharging unit 60 may discharge the flowing gas G₁ and the reaction gas G₂ of the chamber 10.

According to the CVD method of the current embodiment of the present invention, a first flowing gas G₁₁ is set to flow between the susceptor 20 and the satellite disk 40, and a first reaction gas G₂₁ containing a first semiconductor material at a first process temperature T₁ is set to flow to the chamber 10, to form a first semiconductor layer on the substrate 45. That is, the first flowing gas G₁₁ may be supplied to the flowing gas injecting unit 31 via the flowing gas supply line 30, and the first reaction gas G₂₁ may be supplied to the reaction gas injecting unit 50. Also, the first flowing gas G₁₁ may pass through the susceptor flow path 33 to be discharged from the flowing gas discharging unit 35 under the pockets 25. The first flowing gas G₁₁ may include at least one gas selected from the group consisting of Ar, H₂, N₂, He, O₂, CO₂, and NH₃. And the first reaction gas G₂₁ may pass through the nozzle 51 to be discharged from the nozzle hole 53.

The satellite disk 40 mounted in the pockets 25 may float and rotate according to the first flowing gas G₁₁. Here, the first process temperature T₁ may be controlled by the heater 70 and the first flowing gas G₁. That is, the heater 70 may heat the susceptor 20 to a predetermined temperature, and the first flowing gas G₁₁ may be used to control temperatures of the satellite disk 40 and the substrate 45, which is a deposition target, disposed on the susceptor 20. By using a gas having a low thermal conductivity as the first flowing gas G₁₁, the temperatures of the satellite disk 40 and the substrate 45 may be greatly reduced. That is, the first flowing gas G₁₁ having a low thermal conductivity may delay or prevent heat transfer from the susceptor 20 to the satellite disk 40 and the substrate 45.

By setting a second flowing gas G₁₂ to flow between the susceptor 20 and the satellite disk 40 and a second reaction gas G₂₂ containing a second semiconductor material at a second process temperature T₂ to flow into the chamber 10, a second semiconductor layer may be formed. That is, the second flowing gas G₁₂ may be supplied to the flowing gas injecting unit 31 through the flowing gas supply line 30, and the second reaction gas G₂₂ may be supplied to the reaction gas injecting unit 50. The second flowing gas G₁₂ may pass through the susceptor flow path 33 to be discharged from the flowing gas discharging unit 35 under the pockets 25. The second flowing gas G₁₂ may include at least one gas selected from the group consisting of Ar, H₂, N₂, He, O₂, CO₂, and NH₃. And the second reaction gas G₂₂ may pass through the nozzle 51 to be discharged from the nozzle hole 53.

The satellite disk 40 mounted in the pockets 25 may float and rotate according to the second flowing gas G₁₂. Here, the second process temperature T₂ may be controlled by the heater 70 and the second flowing gas G₁₂. That is, the heater 70 may be used to heat the susceptor 20 to a predetermined temperature, and the second flowing gas G₁₂ may be used to control temperatures of the satellite disk 40 and the substrate 45, which is a deposition target, disposed on the susceptor 20. By using a gas having a high thermal conductivity as the second flowing gas G₁₂, the temperatures of the satellite disk 40 and the substrate 45 may be greatly increased. That is, the second flowing gas G₁₂ having a high thermal conductivity may quickly transfer heat from the susceptor 20 to the satellite disk 40 and the substrate 45.

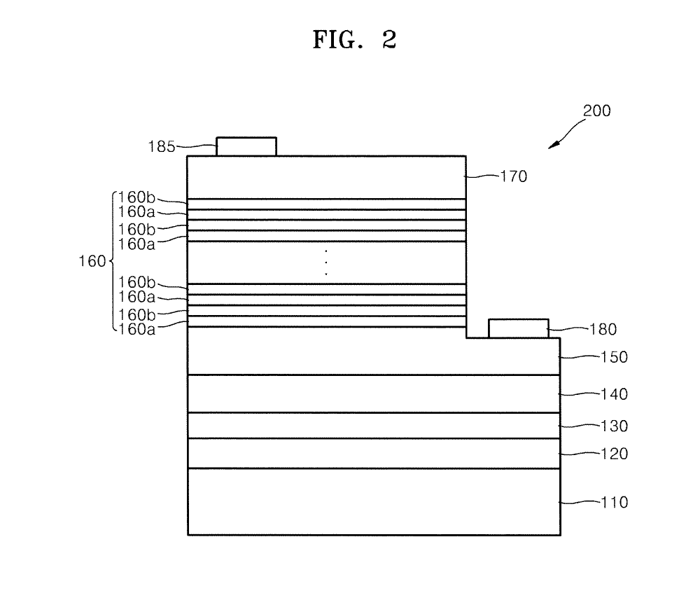

For example, by setting argon (Ar), which is the first flowing gas G₁₁, to flow between the susceptor 20 and the satellite disk 40 and the first reaction gas G₂₁ containing InₓGa₁₋ₓN (0≦x≦1) at a first process temperature T₁ of about 900° C. to flow to the chamber 10, a quantum well layer 160a (see FIG. 2) may be formed on a first conductive type semiconductor layer 150. Also, by setting H₂, which is the second flowing gas G₁₂, between the susceptor 20 and the satellite disk 40, and the second reaction gas G₂₂ containing InₓGa₁₋ₓN (0≦x≦4) at a second process temperature T₂ of about 1000° C., a quantum barrier layer 160b (see FIG. 2) may be formed on the quantum well layer 160a.

As the first flowing gas G₁₁, a gas having a high thermal conductivity may be used, and as the second flowing gas G₁₂, a gas having a low thermal conductivity may be used. That is, different gases having different thermal conductivities may be used as the first and second flowing gases G₁₁ and G₁₂. The flowing gas G₁ having an appropriate thermal conductivity may be selectively supplied according to a process temperature required to grow a semiconductor layer. When a flowing gas G₁ having a relatively low thermal conductivity is supplied to the chamber 10, a temperature of the substrate 45 may be lowered than a process temperature controlled by the heater 70. On the other hand, when a flowing gas G₁ having a relatively high conductivity is supplied to the chamber 10, a temperature of the substrate 45 may be increased to be as high as a process temperature controlled by the heater 70. In addition, according to the CVD method of the current embodiment of the present invention, by adjusting an output of the heater 70 and the flowing gas G₁ at the same time, thereby a process temperature changes more greatly within a short time.

According to the CVD method of the current embodiment of the present invention, the first flowing gas G₁₁ may be supplied to the susceptor 20, and, sequentially, the second flowing gas G₁₂ may be supplied to the susceptor 20. An operation of forming the first and second semiconductor layers may be repeated at least once. The first process temperature T₁ at which the first semiconductor layer is formed and the second process temperature T₂ at which the second semiconductor layer is formed may differ by about 50° to about 150°; for example, the temperature difference may be about 100°.

Also, the CVD method according to the current embodiment of the present invention may further include setting a third flowing gas G₁₃ to flow between the susceptor 20 and the satellite disk 40 and forming a third semiconductor layer on the second semiconductor layer at a third process temperature T₃. The third flowing gas G₁₃ may contain at least one gas selected from the group consisting of Ar, H₂, N₂, He, O₂, CO₂, and NH₃. A thermal conductivity of the third flowing gas G₁₃ may be different from thermal conductivities of the first and second flowing gases G₁₁ and G₁₂. In addition, the third process temperature T₃ may be different from the first and second process temperatures T₁ and T₂. In addition, the CVD method may be a metal organic CVD (MOCVD) method.

While a flowing gas is set to flow to the susceptor 20 and a process temperature is controlled by heating the susceptor 20 according to the current embodiment of the present invention, the embodiment of the present invention is not limited thereto. The process temperature may also be controlled using other methods, for example, by using an apparatus such as a resistance heat apparatus, a lamp, or a radio frequency (RF) heater. Also, the temperature may be controlled using the combination of the fluid gas of the susceptor 20 and the above-described apparatus. Hereinafter, for convenience of description, a method of controlling a temperature by using the flowing gases G₁₁, G₁₂, and G₁₃ in the susceptor 20 will be described.

FIG. 2 is a schematic cross-sectional view illustrating an LED 200 manufactured using the method of manufacturing an LED according to an embodiment of the present invention.

Referring to FIG. 2, the LED 200 may include a substrate 110, a first conductive type semiconductor layer 150, an active layer 160 formed on the first conductive semiconductor layer 150, and a second conductive type semiconductor layer 170 formed on the active layer 160. The LED 200 may further include a buffer layer 120, a low-temperature compound semiconductor layer 130, and an undoped compound semiconductor layer 140 that are sequentially formed between the substrate 110 and the first conductive type semiconductor layer 150.

The first conductive type semiconductor layer 150 may be a compound semiconductor doped with first conductive type impurities. That is, the first conductive type semiconductor layer 150 may be formed by doping a semiconductor material of a composition formula of AlₓIn_{y}Ga_{(1-x-y)}N (here, 0≦x≦1, 0≦y≦1, 0≦x+y≦1) with first conductive type impurities. The compound semiconductor for forming the first conductive type semiconductor layer 150 may be a nitride-based compound semiconductor, and may be, for example, GaN, AlGaN, InGaN, AlGaInN, or the like. The first conductive type impurities may be n-type impurities; examples of the n-type impurities may include Si, Ge, Se, Te, and the like. Thus, the first conductive type semiconductor layer 150 may be an n-type semiconductor layer 150.

The active layer 160 may emit light having a predetermined energy due to recombination of electrons and holes, and may be formed of a semiconductor material such as InₓGa₁₋ₓN (0≦x≦1), so that a band gap energy of the active layer 160 is adjusted according to an indium content. Also, the active layer 160 may be a multi-quantum well (MQW) layer comprising the quantum well layer 160a and the quantum barrier layer 160b that are alternately stacked. The quantum well layer 160a may contain a semiconductor material such as InₓGa₁₋ₓN (0≦x≦1), and the quantum barrier layer 160b may contain a semiconductor material such as GaN or InₓGa₁₋ₓN (0≦x≦4).

The second conductive type semiconductor layer 170 may be a compound semiconductor doped with second conductive type impurities. That is, the second conductive type semiconductor layer 170 may be formed by doping a semiconductor material of a composition formula of AlₓIn_{y}Ga_{(1-x-y)}N (here, 0≦x≦1, 0≦y≦1, and 0≦x+y≦1) with second conductive type impurities. The compound semiconductor for forming the second conductive type semiconductor layer 170 may be a nitride-based compound semiconductor, and may be, for example, GaN, AlGaN, InGaN, AlGaInN, or the like. The second conductive type impurities may be p-type impurities; examples of the p-type impurities may include Mg, Zn, Be, and the like. Thus, the second conductive type semiconductor layer 170 may be a p-type semiconductor layer 170.

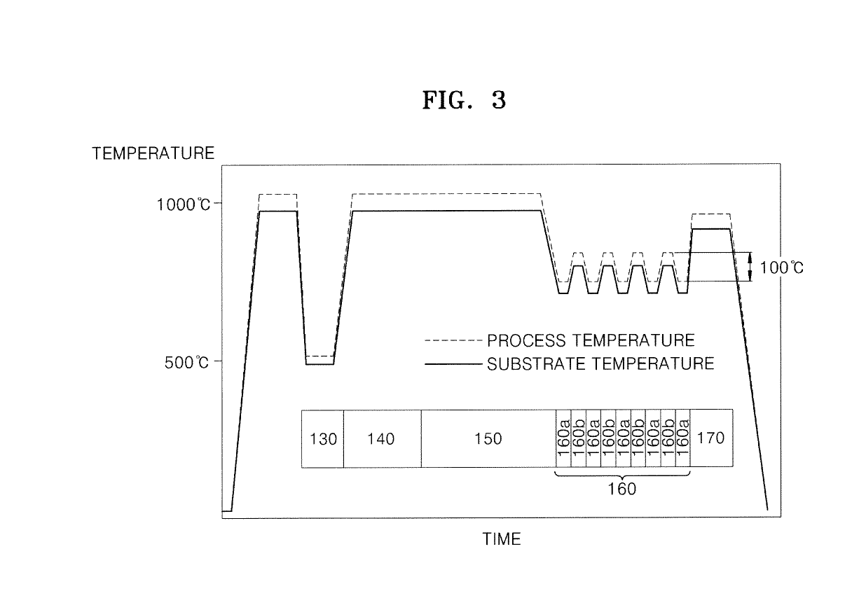

FIG. 3 illustrates a variation in a process temperature and a substrate temperature according to a method of manufacturing an LED of the related art.

Referring to FIG. 3, according to the method of manufacturing an LED of the related art, an active layer 160 is formed at a temperature from about 900° to about 1000°. That is, the active layer 160 may be formed by alternately stacking a quantum well layer 160a and a quantum barrier layer 160b on an n-type semiconductor layer 150. The quantum well layer 160a may be grown at a temperature equal to or less than about 900° to obtain a high composition of In, that is, at a first process temperature T₁; and the quantum barrier layer 160b may be grown at a temperature equal to or greater than about 900° to improve crystalline properties of GaN of the quantum barrier layer 160b, that is, at a second process temperature T₂.

If a difference between the first and second process temperatures T₁ and T₂ is from 50° to about 150°, for example, about 100°, a long period of time may be taken to reach a specific process temperature needed to form a specific semiconductor layer by varying an output of the heater 70. While the process temperature is changing, the growth of the specific semiconductor layer has to be stopped. Also, impurities may be mixed onto a surface of the specific semiconductor layer, interfacial characteristics between the quantum well layer 160a and the quantum barrier layer 160b may be degraded.

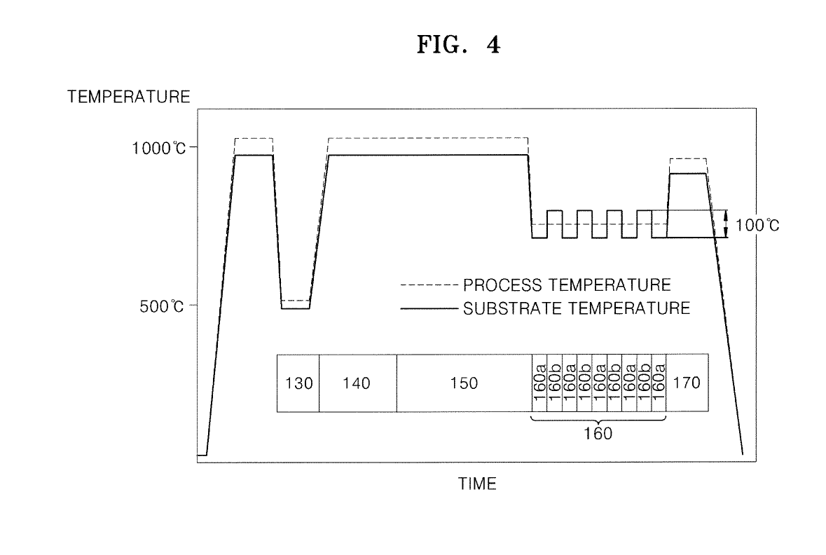

FIG. 4 illustrates a variation in a process temperature and a substrate temperature according to a method of manufacturing an LED according to an embodiment of the present invention.

Referring to FIGS. 1, 2, and 4, first, a buffer layer 120 is formed on a substrate 110 at a high temperature of about 900° or higher. The substrate 110 of FIG. 2 may be the same as the substrate 45 of FIG. 1. A susceptor 20 may be heated using a heater 70 to about 900° or higher so that a temperature of the substrate 110 may be maintained at about 900° or higher. Here, substrate temperature may be measured at a surface of the substrate 110. Then, a low-temperature compound semiconductor layer 130 is formed on the buffer layer 120 at a low temperature of about 500° to about 800°. The low-temperature compound semiconductor layer 130 may be, for example, a low temperature (LT) GaN layer.

Next, an undoped compound semiconductor layer 140 and an n-type semiconductor layer 150 are sequentially formed on the low-temperature compound semiconductor layer 130 at a high temperature of about 1000° to about 1200°. The undoped compound semiconductor layer 140 and the n-type semiconductor layer 150 may respectively be a GaN layer which is not doped, and an n-type GaN layer which is doped with n-type impurities. Then an active layer 160 is formed on the n-type semiconductor layer 150 at a temperature of about 900° to about 1000°. The active layer 160 may be formed by alternately stacking a quantum well layer 160a and a quantum barrier layer 160b on the n-type semiconductor layer 150. The quantum well layer 160a may be grown at a temperature of about 900° or less to obtain a high In content, that is, at a first process temperature T₁. The quantum barrier layer 160b may be grown at a temperature of about 900° or higher to increase crystalline properties of GaN, that is, at a second process temperature T₂.

According to the method of manufacturing an LED of the current embodiment of the present invention, a quantum well layer 160a may be formed on the n-type semiconductor layer 150 by setting a first flowing gas G₁₁ to flow between the susceptor 20 and a satellite disk 40, and setting a first reaction gas G₂₁ containing InₓGa₁₋ₓN(0≦x≦1) at the first process temperature (T₁) of 900° to flow to the chamber 10. That is, the first flowing gas G₁₁ may be supplied to a flowing gas injecting unit 31 via a flowing gas supply line 30, and the first reaction gas G₂₁ may be supplied to a reaction gas injecting unit 50. The first flowing gas G₁₁ may pass through a susceptor flow path 33 to be discharged through from a flowing gas discharging unit 35 under pockets 25. Here, the first flowing gas G₁₁ may contain at least one gas selected from the group consisting of Ar, H₂, N₂, He, O₂, CO₂, and NH₃. And the first reaction gas G₂₁ may pass through the nozzle 51 to be discharged from the nozzle hole 53.

The satellite disk 40 mounted in the pocket 25 may float and rotate according to the first flowing gas G₁₁. The first process temperature T₁ may be controlled by the heater 70 and the first flowing gas G₁₁. That is, the heater 70 may be used to heat the susceptor 20 to a predetermined temperature, and the first flowing gas G₁₁ may be used to control temperatures of the satellite disk 40 and the substrate 45, which is a deposition target, disposed on the heated susceptor 20, that is, the first process temperature T₁. By using a gas having a low thermal conductivity, for example, Ar, as the first flowing gas G₁₁, the temperatures of the satellite disk 40 and the substrate 45 may be greatly reduced. That is, the first flowing gas G₁₁ having a low thermal conductivity may delay or prevent heat transfer from the susceptor 20 to the satellite disk 40 and the substrate 45.

Also, by setting a second flowing gas G₁₂ to flow between the susceptor 20 and the satellite disk 40 and a second reaction gas G₂₂ containing GaN or InₓGa₁₋ₓN (0≦x≦0.4) at a second process temperature T₂ of 1000°, to flow to the chamber 10, the quantum barrier layer 160b may be formed. That is, the second flowing gas G₁₂ may be supplied to the flowing gas injecting unit 31 via the flowing gas supply line 30, and the second reaction gas G₂₂ may be supplied to the reaction gas injecting unit 50. Also, the second flowing gas G₁₂ may be passed through the susceptor 20 to be discharged through from the flowing gas discharging unit 35 under the pockets 25. The second flowing gas G₁₂ may contain at least one gas selected from the group consisting of Ar, H₂, N₂, He, O₂, CO₂, and NH₃. The second reaction gas G₂₂ may pass through the nozzle 51 to be discharged from the nozzle hole 53.

The satellite disk 40 mounted in the pockets 25 may float and rotate according to the second flowing gas G₁₂. The second process temperature T₂ may be controlled by the heater 70 and the second flowing gas G₁₂. That is, the heater 70 may heat the susceptor 20 to a predetermined temperature, and the second flowing gas G₁₂ may control temperatures of the satellite disk 40 and the substrate 45, which is a deposition target, disposed on the susceptor 20, that is, the second process temperature T₂. By using a gas having a high thermal conductivity, for example, H₂, as the second flowing gas G₁₂, the temperatures of the satellite disk 40 and the substrate 45 may be greatly increased. That is, the second flowing gas G₁₂ having a high thermal conductivity may quickly transfer heat from the susceptor 20 to the satellite disk 40 and the substrate 45.

According to the method of manufacturing an LED of the current embodiment of the present invention, a thermal conductivity of the first flowing gas G₁₁ may be different from a thermal conductivity of the second flowing gas G₁₂. That is, a flowing gas G₁ having a predetermined thermal conductivity may be selectively supplied according to a process temperature needed to grow a semiconductor layer. When supplying the flowing gas G₁ having a relatively low thermal conductivity to the susceptor 20, the temperature of the substrate 45 may be lowered than a process temperature controlled by the heater 70. On the other hand, when supplying a flowing gas G₁ having a relatively high thermal conductivity to the susceptor 20, the temperature of the substrate 45 may be increased as high as a process temperature controlled by the heater 70. In addition, according to the method of manufacturing an LED of the current embodiment of the present invention, an output of the heater 70 and the flowing gas G₁ may vary at the same time, thereby varying the process temperature more greatly within a short time.

Also, according to the method of manufacturing an LED of the current embodiment of the present invention, the operation of forming the quantum well layer 160a and the quantum barrier layer 160b may be repeated at least once. A difference between the first process temperature T₁ at which the first semiconductor layer is formed and the second process temperature T₂ at which the second semiconductor layer is formed may be from about 50° to about 150°, and for example, about 100°.

Next, at a high temperature of about 1000° to about 1200°, a p-type semiconductor layer 170 is formed on the active layer 160. Also, by using mesa etching, an n-type electrode 180 may be formed on an n-type semiconductor layer 150, and a p-type electrode 185 may be further formed on the p-type semiconductor layer 170. The method of manufacturing an LED of the current embodiment of the present invention may be an MOCVD method.

According to the method of manufacturing an LED of the current embodiment of the present invention, a quantum well layer 160a may be formed at a first process temperature T₁ of about 900°, and then without delay, a quantum barrier layer 160b may be formed at a second process temperature T₂ of about 1000° which is about 100° higher than the first process temperature T₁. According to the method of manufacturing an LED of the current embodiment of the present invention, when various semiconductor layers are formed by crystal growth at various temperatures, a flowing gas G₁ may vary to thereby quickly vary a process temperature. Accordingly, the time for forming semiconductor layers by crystal growth may be reduced, and crystal-growths of the semiconductor layers may be continued also while the process temperature is varied. In addition, according to the method of manufacturing an LED of the current embodiment of the present invention, interfacial properties of the quantum well layer 160a and the quantum barrier layer 160b may be improved, thereby improving light-emitting efficiency of an LED.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A chemical vapor deposition (CVD) method, the method comprising:
forming a first semiconductor layer on a substrate that is mounted on a satellite disk at a first process temperature; and
forming a second semiconductor layer on the first semiconductor layer at a second process temperature,
wherein the forming the first and second semiconductor layers is performed at least once.

2. The CVD method of claim 1, further comprising controlling the first and second process temperatures by first and second flowing gases flowing to a susceptor, respectively.

3. The CVD method of claim 2, wherein a thermal conductivity of the first flowing gas is different from a thermal conductivity of the second flowing gas.

4. The CVD method of claim 2, wherein each of the first and second flowing gases includes at least one selected from the group consisting of Ar, H₂, N₂, He, O₂, CO₂, and NH₃.

5. The CVD method of claim 1, wherein a difference between the first and second process temperatures is from about 50° to about 150°.

6. The CVD method of claim 1, further comprising forming a third semiconductor layer on the second semiconductor layer at a third process temperature.

7. The CVD method of claim 6, further comprising controlling a third process temperature by a third flowing gas flowing to a susceptor.

8. A method of manufacturing a light-emitting device (LED) by using a chemical vapor deposition (CVD) method, the method comprising:
forming a quantum well layer on a substrate that is mounted on a satellite disk at a first process temperature; and
forming a quantum barrier layer on the quantum well layer at a second process temperature,
wherein the forming the quantum well layer and the quantum barrier layer is performed at least once.

9. The method of claim 8, further comprising controlling the first and second process temperatures by using first and second flowing gases flowing to a susceptor, respectively.

10. The method of claim 9, wherein a thermal conductivity of the first flowing gas is different from a thermal conductivity of the second flowing gas.

11. The method of claim 9, wherein a thermal conductivity of the first flowing gas is less than a thermal conductivity of the second flowing gas.

12. The method of claim 9, wherein each of the first and second flowing gases includes at least one selected from the group consisting of Ar, H₂, N₂, He, O₂, CO₂, and NH₃.

13. The method of claim 9, wherein the first flowing gas is Ar, and the second flowing gas is H₂.

14. The method of claim 9, wherein the first flowing gas is N₂, and the second flowing gas is H₂.

15. The method of claim 8, wherein the first process temperature is from about 900° to about 1200°.

16. The method of claim 8, wherein the second process temperature is from about 900° to about 1200°.

17. The method of claim 7, wherein a difference between the first and second process temperatures is from about 50° to about 150°.

18. The method of claim 8, wherein each of the quantum well layer and the quantum barrier layer comprises at least one selected from the group consisting of GaN, GaInN, AlGaN, and AlGaInN.

19. The method of claim 8, wherein the quantum well layer comprises InₓGa₁₋ₓN (0≦x≦1).

20. The method of claim 8, wherein the quantum barrier layer comprises InₓGa₁₋ₓN (0≦x≦0.4).
